(19) United States
(12) Patent Application Publication
(10) Pub. No.: US 2007/0015306 A1
(43) Pub. Date: Jan. 18, 2007

(54) Manufacturing method of P type group III nitride semiconductor layer and light emitting device

(75) Inventors: Shun Takanami, Soraku-gun (JP); Kazuhiro Nishizono, Soraku-gun (JP); Yoshiyuki Kawaguchi, Soraku-gun (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION

(21) Appl. No.: 11/485,232

(22) Filed: Jul. 11, 2006

(30) Foreign Application Priority Data
Jul. 13, 2005 (JP) 2005-204188

(51) Int. Cl. H01L 21/00

(52) U.S. Cl. 438/77

(57) ABSTRACT

A p type group III nitride semiconductor layer can be manufactured without causing its crystal deterioration, and without requiring any complicated post-treatment, by repeating a plurality of times the following steps: the step A of growing a group III nitride semiconductor layer containing p type impurities; the step B of discontinuing the growth of the group III nitride semiconductor layer by stopping supplies of the respective material gases and the carrier gas, and replacing an atmospheric gas within a film forming apparatus with an inert gas, and reducing a temperature of the substrate from a growth temperature; and the step C of resuming the growth of the group III nitride semiconductor layer by again raising the temperature of the substrate and supplying the material gases and the carrier gas into the film forming apparatus. Thereby, the activation of the semiconductor layer is attainable by releasing hydrogen incorporated into the semiconductor layer, and reducing thermal damage, resulting in suppressing the crystal deterioration.

Priority is claimed to Japanese Patent Application No. 2005-204188 filed on Jul. 13, 2005, the disclosure of which is incorporated by reference in its entirety.

### BACKGROUND OF THE INVENTION

1. Field of the Invention

The present invention relates to a manufacturing method of a p type group III nitride semiconductor layer used in semiconductor elements such as light emitting devices using a group III nitride semiconductor layer and, in particular, to a manufacturing method of a low-resistance p type group III nitride semiconductor layer with p type impurities highly activated.

2. Description of Related Art

As a light emitting device such as a blue or ultraviolet light emitting diodes (LED), a light emitting device using a group III nitride semiconductor is widely known. In order to utilize the group III nitride semiconductor in light emitting devices, it is necessary to control the electric conductivity of p type and n type of the group III nitride semiconductor. An n type conductivity (n type) gallium nitride semiconductor layer can be formed with relative ease by adding Si as impurity material. On the other hand, a p type conductivity (p type) gallium nitride semiconductor layer suffers from the following problem. That is, merely doping of acceptor impurities such as Mg and Zn results in a low activation rate of impurities, because of bonding and incorporating of hydrogen, thus failing to obtain a low-resistance p type gallium nitride semiconductor layer.

To overcome this problem, Japanese Patent No. 2540791 discloses a method for improving activation rate by forming a group III nitride semiconductor layer doped with p type impurities, followed by heat treatment at temperatures of 400° C. and above in an atmosphere substantially free of hydrogen.

With this method, however, the formed group III nitride semiconductor layer is exposed to high temperatures for a long period of time, which can cause nitrogen escape from the group III nitride semiconductor layer and a deterioration of surface morphology. This makes it difficult to improve the light emitting characteristic and the yield of a semiconductor device such as a light emitting device.

On the other hand, Japanese Patent No. 3509514 discloses a method for manufacturing a low-resistance group III nitride semiconductor layer by forming a metal thin film on a surface of a group III nitride semiconductor layer with acceptor impurities added, followed by heat treatment.

This method requires the step of forming the metal thin film on the surface of the group III nitride semiconductor layer after termination of crystal growth, the step of heat treatment, and the step of removing the metal thin film. This complicates the process. In addition, there is a fear that the group III nitride semiconductor layer has a rough surface due to diffusion of metal.

### SUMMARY OF THE INVENTION

The present invention provides a manufacturing method of a p type group III nitride semiconductor layer, with which a p type group III nitride semiconductor layer containing p type impurities can be manufactured reliably without causing a deterioration of the crystals thereof, and without requiring any complicated step. The present invention also provides a high-performance light emitting device obtainable from the manufacturing method.

In a manufacturing method of the present invention, a p type group III nitride semiconductor layer is grown on a substrate disposed within a film forming apparatus by using a material gas of a group III element, a material gas of p type impurities, a material gas of nitrogen, and a carrier gas. Specifically, the manufacturing method includes: a step A of growing a group III nitride semiconductor layer containing p type impurities; a step B of discontinuing the growth of the group III nitride semiconductor layer by stopping supplies of the respective material gases and the carrier gas, and replacing an atmospheric gas within the film forming apparatus with an inert gas, and reducing a temperature of the substrate from a growth temperature; and a step C of resuming the growth of the group III nitride semiconductor layer by again raising the temperature of the substrate and supplying the respective material gases and the carrier gas into the film forming apparatus. These steps A to C are repeated a plurality of times to form the p type group III nitride semiconductor layer.

Preferably, in the step B of the above manufacturing method, a time interval of discontinuing the growth of the group III nitride semiconductor layer is 1 to 10 minutes, and the temperature of the substrate is reduced to 500 to 900° C.

With this method, after growing the group III nitride semiconductor layer containing p type impurities, the growth of the group III nitride semiconductor layer is discontinued by stopping the supplies of the material gases and the carrier gas, and then the atmospheric gas within the film forming apparatus is replaced with the inert gas. This allows for release of the hydrogen incorporated into the semiconductor layer, enabling the activation of the p type group III nitride semiconductor layer. Further, after the step of reducing the temperature of the substrate from the growth temperature, the growth of the group III nitride semiconductor layer is resumed by again raising the temperature of the substrate and supplying the material gases and the carrier gas into the film forming apparatus. Therefore, the substrate temperature during p type activation process is lower than the growth temperature of the p type group III nitride semiconductor layer, thus permitting the activation with a reduction in the thermal damage to the p type group III nitride semiconductor layer.

When the p type group III nitride semiconductor layer is grown without discontinuing the growth as in the case with the conventional method, hydrogen in deep position is hard to escape under the heat treatment after the growth. In the present invention, the p type group III nitride semiconductor layer can be obtained by repeating the above-mentioned steps A to C, including the growth discontinuation. It is therefore possible to grow the respective layers thinly, and facilitate release of hydrogen during the growth discontinuation, permitting a reliable activation in a short period of time. Further, because the p type group III nitride semiconductor layer can be formed by the activation in a short period of time, it is possible to reduce nitrogen escape from the p type group III nitride semiconductor layer, and suppress a deterioration of surface morphology. Furthermore, defects such as nitrogen escape and a deterioration of surface morphology can be recovered by regrowth.

Preferably, the above-mentioned material gas of a group III element contains any one of Al, Ga, and In. Preferably, the above-mentioned material gas of p type impurities is composed of biscyclopentadienyl magnesium, bisethylcyclopentadienyl magnesium, diethyl zinc, or dimethyl zinc.

A light emitting device of the present invention has a semiconductor layer containing the p type group III nitride semiconductor layer manufactured by the above-mentioned manufacturing method of the present invention. This makes possible to obtain a low-resistance p type group III nitride semiconductor layer with p type impurities highly activated, resulting in a high-performance light emitting device.

### BRIEF DESCRIPTION OF THE DRAWINGS

FIG. 1 is a sectional view illustrating an example of preferred embodiments of a light emitting device that can be obtained by a manufacturing method of a p type group III nitride semiconductor layer in the present invention;

FIG. 2 is a graph showing a temperature profile of the manufacturing method of a p type group III nitride semiconductor layer of the present invention, along with a timing chart illustrating supply timings of respective types of gases;

FIG. 3 is a sectional view of a light emitting device according to Example 1 of the present invention; and

FIG. 4 is a sectional view of a light emitting device according to Example 2 of the present invention.

### DESCRIPTION OF PREFERRED EMBODIMENTS

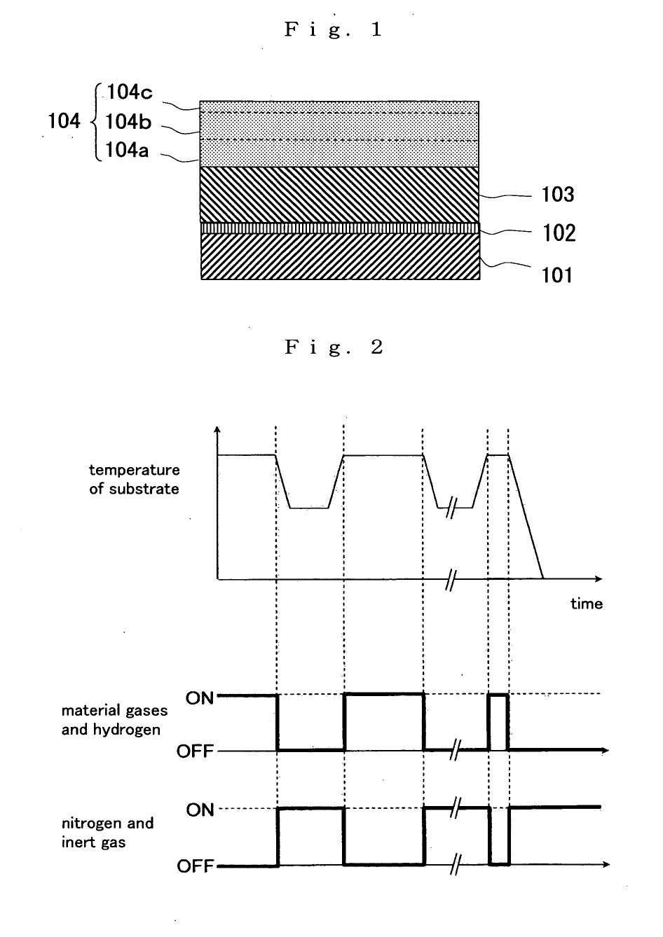

A manufacturing method of a p type group III nitride semiconductor layer of the present invention will be described below in detail. FIG. 1 is a schematic sectional view illustrating an example of preferred embodiments of a p type group III nitride semiconductor layer that can be obtained by a manufacturing method of the present invention.

In FIG. 1, the reference numeral 101 designates a substrate that is used for growing a group III nitride semiconductor layer. Specifically, the substrate is of sapphire, silicon carbide (SiC), gallium nitride (GaN), zinc oxide (ZnO), or zirconium diboride (ZrB₂). Examples of a method for growing the group III nitride semiconductor layer are metal organic chemical vapor deposition method (MOCVD method), gas source molecular beam epitaxy method (GS-MBE method), and hydride vapor phase epitaxy method (HVPE method).

Referring to FIG. 1, a buffer layer 102, an undoped group III nitride semiconductor layer 103, and a p type group III nitride semiconductor layer 104 are formed in this order on the substrate 101, resulting in a light emitting device. The p type group III nitride semiconductor layer 104 is grown with any one of material gases of Al, Ga, and In, a p type impurities gas, and a nitrogen material gas, and carrier gases of these material gases. The p type group III nitride semiconductor layer 104 is grown by periodically inserting a growth discontinuous time in the growth step thereof. Stopping the supplies of the material gases and the carrier gases causes the growth discontinuation. A nitrogen gas or an inert gas is used as the atmospheric gas during the growth discontinuation.

The temperature profile of the substrate 101 during the growth discontinuation consists of, as shown in FIG. 2, a temperature drop from a growth temperature of the p type group III nitride semiconductor layer 104, a temperature retention during a period of time, and a temperature rise of the p type group III nitride semiconductor layer 104 to the growth temperature thereof. Thereafter, the material gases and the carrier gases are again supplied to resume the growth of the p type group III nitride semiconductor layer 104.

Repeating a series of the above-mentioned steps produces the p type group III nitride semiconductor layer 104 of a laminate structure indicated by the reference numerals 104a to 104c. Although in the profile of FIG. 2, the temperature is retained at a constant temperature after reducing the temperature of the substrate 101, the temperature may be raised without retaining at the constant temperature after reducing the temperature of the substrate 101, or the growth may be resumed while raising the temperature. This is because it is important that after stopping the supplies of the material gases and the carrier gases, the growth is discontinued, and the atmosphere is replaced with the inert gas, and then the temperature of the substrate 101 is reduced than the growth temperature. Here, the time interval of retaining at the constant temperature is from zero to less than 10 minutes, and preferably 0 to 8 minutes. Needless to say, the retention time is shorter than the growth discontinuous time.

Specifically, the p type group III nitride semiconductor layer 104 can be manufactured by repeating a plurality of times the following steps: the step A of growing a group III nitride semiconductor layer containing p type impurities; the step B of discontinuing the growth of the group III nitride semiconductor layer by stopping the supplies of the respective material gases and their respective carrier gases, and replacing an atmospheric gas within the film forming apparatus with a nitrogen gas or the like, and reducing a temperature of the substrate 101 from a growth temperature; and the step C of resuming the growth of the group III nitride semiconductor layer by again raising the temperature of the substrate 101 and supplying the respective material gases and the carrier gases into the film forming apparatus. During the growth discontinuation, the atmosphere is pressurized to a degree that nitrogen is not decomposed and not released from the p type group III nitride semiconductor layer 104.

Strictly speaking, the p type group III nitride semiconductor layer 104 is not of p type because the p type impurities are not activated during the growth, that is, a mere group III nitride semiconductor layer. During the growth discontinuation step, the p type impurities are activated, resulting in the p type group III nitride semiconductor layer 104.

Examples of the p type impurities are magnesium and zinc, or the like. The material gas of p type impurities is composed of biscyclopentadienyl magnesium (Cp₂Mg:(C₅H₅)₂Mg), bisethylcyclopentadienyl magnesium (EtCp₂Mg:(C₅H₄C₂H₅)₂Mg), diethyl zinc (DEZ:(C₂H₅)₂Zn), dimethyl zinc (DMZ:(CH₃)₂Zn), or the like.

The time interval of discontinuing the growth of the p type group III nitride semiconductor layer 104 is about 1 to 10 minutes. When this time interval is below one minute, the p type impurities cannot be activated sufficiently. When it is over ten minutes, there may occur nitrogen escape from the crystals of the p type group III nitride semiconductor layer 104, and a deterioration of surface morphology. The term “the time interval of discontinuing the growth” means the time between the stop of supplies of the material gases and the carrier gases, and the resumption of supplies of the material gases and the carrier gases.

When discontinuing the growth of the p type group III nitride semiconductor layer 104, the temperature of the substrate 101 is reduced preferably in a range of 500 to 900° C. Below 500° C., the p type impurities cannot be activated sufficiently. Over 900° C., there may occur nitrogen escape from the crystals of the p type group III nitride semiconductor layer 104, and a deterioration of surface morphology. The temperature of the substrate 101 when growing the p type group III nitride semiconductor layer 104 is 700 to 1100° C. Hence, the range of temperature drop at the time of discontinuing the growth of the p type group III nitride semiconductor layer 104 and then reducing the temperature of the substrate 101 is preferably about 50° C. to 600° C., and more preferably about 200° C. to 400° C.

Preferably, anitrogen gas is used as the inert gas, because it prevents decomposition of the group III nitride semiconductor, and has a small reactivity with the group III nitride semiconductor. During the growth discontinuation step, it is preferable to control the pressure of the atmospheric gas by pressurization of not less than the decomposition pressure of the p type group III nitride semiconductor, in order to prevent nitrogen escape from the p type group III nitride semiconductor layer 104. For GaN, the decomposition pressure is about 0.01 atmospheric pressure at 800° C., and about 0.1 atmospheric pressure at 1000° C. Therefore, it is preferable to carry out pressurization of not less than the above-mentioned atmospheric pressure during the growth discontinuation step.

Although in the p type group III nitride semiconductor layer 104 of the laminate structure of the present invention, no particular limitations are imposed on the number of layers (the number of repetitions of the above-mentioned steps A to C), it is preferable to use a laminate consisting of about 2 to 500 layers of the p type group III nitride semiconductor layer. That is, the above-mentioned steps A to C are repeated not less than two times and not more than 500 times. Over 500 layers, it is difficult to manufacture the p type group III nitride semiconductor layer 104 that is efficient for activation by taking out hydrogen from the group III nitride semiconductor layer.

In the p type group III nitride semiconductor layer 104 of the laminate structure of the present invention, the number of repetitions of the procedure of discontinuation and regrowth (the number of laminations) can be determined suitably according to the desired thickness and the growth film thickness per repetition of the steps A to C. Hence, no particular limitations are imposed on the number of laminations. However, a suitable number of laminations is 2 to 500. This is because the growth film thickness per layer is 2 to 200 nm in consideration of flatness and coating property of the layers, and a reduction in discontinuous time. The laminated layers are not necessarily to have the same thickness.

In the manufacturing method of the present invention, when forming the p type group III nitride semiconductor layer 104 of the laminate structure, it is preferable that a p type group III nitride semiconductor layer 104c, which is formed on the uppermost surface, has a smaller thickness than underlying p type group III nitride semiconductor layers 104a and 104b. Alternatively, the uppermost p type group III nitride semiconductor layer 104c may be laminated through a plurality of repetitions. In this case, the hydrogen incorporated into the uppermost p type group III nitride semiconductor layer 104c can be released only by the step of natural cooling after termination of the growth of the p type group III nitride semiconductor layer 104. This enables the p type group III nitride semiconductor layer 104 to be manufactured without requiring reheating, which has been required conventionally.

The natural cooling depends on the atmospheric temperature, the heat capacity of the apparatus, and the like. The cooling proceeds usually at a temperature gradient of 10 to 200° C./min.

Preferably, the thickness of the uppermost p type group III nitride semiconductor layer 104c is not more than 100 nm. Exceeding 100 nm, the p type impurities cannot be activated sufficiently.

### EXAMPLES

The following examples illustrate the manner in which the present invention can be practiced. It is understood, however, that the examples are for the purpose of illustration and the invention is not to be regarded as limited to any of the specific materials or condition therein.

### Example 1

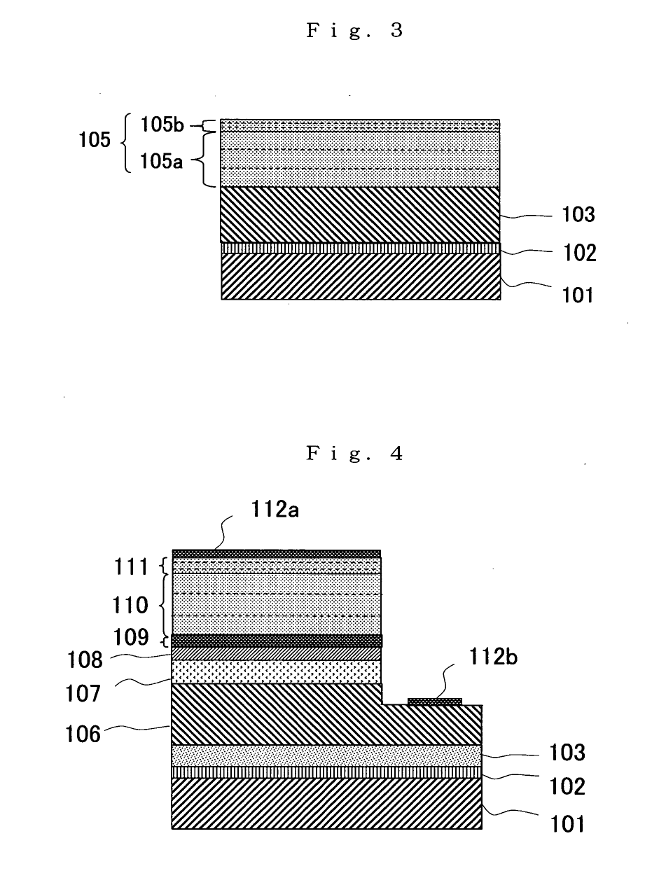

In order to confirm the activation of the p type impurities in the manufacturing method of the present invention, a GaN buffer layer 102, an undoped GaN layer 103, a p type GaN layer 105 were grown on a substrate 101 made of sapphire as shown in FIG. 3. Specifically, the substrate 101 made of sapphire was set at a predetermined position within a growth furnace for MOCVD as a film forming apparatus, so that a (0001)-oriented plane of sapphire was a growth plane. Then, the GaN buffer layer 102 was grown at 600° C. That is, the GaN buffer layer 102 was grown in a thickness of 20 nm by using trimethyl gallium (TMG:Ga(CH₃)₃) and ammonia (NH₃) gas as material gas.

Subsequently, the temperature of the substrate 101 was raised to 1050° C., and at this growth temperature, the undoped GaN layer 103 was grown as the under layer of the p type GaN layer 105. The undoped GaN layer 103 was grown in a thickness of 2 μm by using TMG and ammonia gas as material gas.

Thereafter, a p type GaN layer 105a having a total thickness of 300 nm, into which p type impurities were added, was grown in the following manner. (1) It was grown in a thickness of 100 nm by using an atmospheric gas composed of TMG, ammonia gas, a material gas consisting of biscyclopentadienyl magnesium (Cp₂Mg) as a p type impurities material gas, and a carrier gas (a hydrogen gas). (2) The growth was discontinued by stopping the supplies of the material and the carrier gas. The atmospheric gas was replaced with a nitrogen gas, and the temperature of the substrate 101 was reduced to 850° C. in 3 minutes, and retained as it was for 5 minutes. During the growth discontinuation, the atmosphere was pressurized to a degree that nitrogen was decomposed but not released from the p type GaN layer 105a. (3) The temperature of the substrate 101 was again raised to 1050° C. in 3 minutes. The foregoing steps (1) to (3) were repeated three times.

Next, from the state that the temperature of the substrate 101 was 1050° C., a p type GaN contact layer 105b having a total thickness of 30 nm, into which p type impurities were added, was formed in the following steps. (1) It was grown in a thickness of 10 nm by using an atmospheric gas composed of a material gas consisting of TMG, an ammonia gas, and Cp₂Mg, and a carrier gas (a hydrogen gas). (2) The growth was discontinued by stopping the supplies of the material gas and the carrier gas. The atmospheric gas was replaced with a nitrogen gas, and the temperature of the substrate 101 was reduced to 850° C. in 3 minute, and retained as it was for 5 minutes. During the growth discontinuation, the atmosphere was pressurized to a degree that nitrogen was not decomposed and not released from the p type GaN layer 105b. (3) The temperature of the substrate 101 was again raised to 1050° C. in 3 minute. The foregoing steps (1) to (3) were repeated three times, followed by natural cooling in the growth furnace.

By observing on a microscope the surface of the p type GaN layer 105 so manufactured as a sample, it was found that the surface morphology was superior, namely being free of nitrogen escape and having superior crystallinity. Further, the measurement of holes in the p type GaN layer 105 was made to find the hole concentration thereof. The result was 2×10¹⁸ cm⁻³, and hence the activation was confirmed.

### Comparative Example 1

On a sapphire substrate, a GaN buffer layer 102 was grown in a thickness of 20 nm, an undoped GaN layer 103 was grown in a thickness of 2 μm, a p type GaN layer 105a was grown in a thickness of 300 nm, and a p type GaN contact layer 105b was grown in a thickness of 30 nm in the same manner as in Example 1, except that a p type GaN layer 105a and a p type GaN contact layer 105b were grown only by a single continuous procedure without the step of growth discontinuation.

The sample so manufactured was retained at 750° C. in an atmosphere of nitrogen for 20 minutes, followed by heat treatment. Thereafter, the measurement of holes was made to find the hole concentration thereof. The result was 2×10¹⁷ cm⁻³, namely an order of magnitude smaller than that of the sample obtained in Example 1.

### Example 2

A light emitting device (LED) as shown in FIG. 4 was manufactured with the manufacturing method of the p type group III nitride semiconductor layer 104 in the present invention.

A substrate 101 made of sapphire was set at a predetermined position within a growth furnace for MOCVD so that its (0001)-oriented plane was a growth plane. Then, the GaN buffer layer 102 was grown at 600° C. Specifically, the GaN buffer layer 102 was grown in a thickness of 20 nm by using TMG and ammonia gas as material gas.

Subsequently, the temperature of the substrate 101 was raised to 1050° C., and at this growth temperature, an undoped GaN layer 103 was grown as the under layer of an n type GaN layer 106. The undoped GaN layer 103 was grown in a thickness of 2 μm by using TMG and ammonia gas as material gas.

After raising the temperature of the substrate 101 to 1050° C., an Si-doped n type GaN layer 106 was formed in a thickness of 2 μm by using TMG, ammonia gas, and silan (SiH₄)as the material gas of silicon (Si). Then, an InGaN layer 107 was formed in a thickness of 0.5 μm by using a material gas containing trimethyl indium (TMI:In(CH₃)₃) and TMG. The temperature of the substrate 101 was temporarily reduced to 750° C. in 4.5 minute, and an InGaN layer/GaN layer (a quantum well layer) 108 as an active layer was formed in a thickness of 50 nm, while continuously allowing TMI to flow intermittently. The temperature of the substrate 101 was again raised to 1050° C. in 4.5 minute.

Next, a p type AlGaN cap layer 109 having a total thickness of 30 nm, into which p type impurities were added, was formed in the following manner. (1) It was grown in a thickness of 15 nm by using an atmospheric gas composed of a material gas consisting of TMG, trimethylaluminium(TMA:Al(CH₃)₃), ammonia gas, andCp₂Mg, and a carrier gas (a hydrogen gas). (2) The growth was discontinued by stopping the supplies of the material gas and the carrier gas. The atmospheric gas was replaced with a nitrogen gas, and the temperature of the substrate 101 was reduced to 850° C. in 3 minute, and retained as it was for 5 minutes. During the growth discontinuation, the atmosphere was pressurized to a degree that nitrogen was not decomposed and not released from the p type AlGaN cap layer 109. (3) The temperature of the substrate 101 was again raised to 1050° C. in 3 minutes. The foregoing steps (1) to (3) were repeated two times.

Next, a p type GaN clad layer 110 having a total thickness of 300 nm, into which p type impurities were added, was formed in the following manner. (1) It was grown in a thickness of 100 nm by using an atmospheric gas composed of a material gas consisting of TMG, ammonia gas, and Cp₂Mg, and a carrier gas (a hydrogen gas). (2) The growth was discontinued by stopping the supplies of the material gas and the carrier gas. The atmospheric gas was replaced with a nitrogen gas, and the temperature of the substrate 101 was reduced to 850° C. in 3 minutes, and retained as it was for 5 minutes. During the growth discontinuation, the atmosphere was pressurized to a degree that nitrogen was not decomposed and not released from the p type GaN clad layer 110. (3) The temperature of the substrate 101 was again raised to 1050° C. in 3 minutes. The foregoing steps (1) to (3) were repeated three times.

Finally, a p type GaN contact layer 111 having a total thickness of 30 nm, into which p type impurities were added, was formed in the following manner. (1) It was grown in a thickness of 10 nm by using an atmospheric gas composed of a material gas consisting of TMG, ammonia gas, and Cp₂Mg, and a carrier gas (a hydrogen gas). (2) The growth was discontinued by stopping the supplies of the material gas and the carrier gas. The atmospheric gas was replaced with a nitrogen gas, and the temperature of the substrate 101 was reduced to 850° C. in 3 minutes, and retained as it was for 5 minutes. During the growth discontinuation, the atmosphere was pressurized to a degree that nitrogen was not decomposed and not released from the p type GaN contact layer 111. (3) The temperature of the substrate 101 was again raised to 1050° C. in 3 minutes. The foregoing steps (1) to (3) were repeated three times.

Thereafter, a resist was applied with a predetermined mask by photolithography method, and then a partial region up to the n type GaN layer 106 was etched away by reactive ion etching (RIE) method. After etching, a p type electrode 112a obtained by laminating an Ni layer and an Au layer, and an n type electrode 112b obtained by laminating a Ti layer and an Al layer, were formed by photolithography method. This resulted in the light emitting device (a light emitting device A) as shown in FIG. 4.

### Comparative Example 2

A group III nitride semiconductor layer as shown in FIG. 4 was grown in the same manner as in Example 2, except that an AlGaN cap layer 109 having a thickness of 30 nm, into which p type impurities were added, aGaN clad layer 110 having a thickness of 300 nm, and a GaN contact layer 111 having a thickness of 30 nm were grown on an InGaN layer/GaN layer 108 as an active layer, without the step of growth discontinuation.

Thereafter, the activation of the p type impurities was carried out by heat treatment at 750° C. in an atmosphere of nitrogen. Then, the same device process as in Example 2 was performed to manufacture a light emitting device (a light emitting device B).

<Evaluation>

Before forming a p type electrode 112a and an n type electrode 112b in each of the manufactured light emitting devices A and B, the surfaces of the GaN contact layer 111 and the n type GaN layer 106 were observed on a microscope, and no difference in surface morphology was observed. However, there was the following difference. That is, after forming the p type electrode 112a and the n type electrode 112b, the measurement of current-light output was made. Under 20 mA of forward current, the light output of the light emitting device A exhibited on the average an improvement of 10% of magnitude than that of the light emitting device B.

In other words, the present invention is capable of manufacturing a light emitting device having characteristics superior to that of the conventional one, without requiring any heat treatment furnace and heat treatment step that are needed in heat treatment at 750° C. in an atmosphere of nitrogen, in order to conduct the activation of p type impurities. Consequently, the present invention enables the p type group III nitride semiconductor layer and the light emitting device to be manufactured at high efficiency and low costs, with the manufacturing steps omitted.

What is claimed is:

1. A manufacturing method of a p type group III nitride semiconductor layer in which a p type group III nitride semiconductor layer is grown on a substrate disposed within a film forming apparatus by using a material gas of a group III element, a material gas of p type impurities, a material gas of nitrogen, and a carrier gas, the method comprising:
a step A of growing a group III nitride semiconductor layer containing p type impurities;
a step B of discontinuing the growth of the group III nitride semiconductor layer by stopping supplies of the respective material gases and the carrier gas, and replacing an atmospheric gas within the film forming apparatus with an inert gas, and reducing a temperature of the substrate from a growth temperature; and
a step C of resuming the growth of the group III nitride semiconductor layer by again raising the temperature of the substrate and supplying the respective material gases and the carrier gas into the film forming apparatus,
these steps A to C being repeated a plurality of times to form the p type group III nitride semiconductor layer.

2. The manufacturing method of a p type group III nitride semiconductor layer according to claim 1 wherein,
the group III element material gas contains at least one selected from the group consisting of Al, Ga, and In.

3. The manufacturing method of a p type group III nitride semiconductor layer according to claim 1 wherein,
the p type impurities material gas is composed of at least one selected from the group consisting of biscyclopentadienyl magnesium, bisethylcyclopentadienyl magnesium, diethyl zinc, and dimethyl zinc.

4. The manufacturing method of a p type group III nitride semiconductor layer according to claim 1 wherein,
a time interval of discontinuing the growth of the group III nitride semiconductor layer in the step B is 1 to 10 minutes.

5. The manufacturing method of a p type group III nitride semiconductor layer according to claim 1 wherein,
the temperature of the substrate is reduced to 500 to 900° C. in the step B.

6. The manufacturing method of a p type group III nitride semiconductor layer according to claim 1 wherein,
the inert gas is a nitrogen gas in the step B.

7. The manufacturing method of a p type group III nitride semiconductor layer according to claim 1 wherein,
in the step B, a pressure of an atmospheric gas within the film forming apparatus is controlled to be not less than a decomposition pressure of the group III nitride semiconductor layer.

8. The manufacturing method of a p type group III nitride semiconductor layer according to claim 1 wherein,
the number of repetitions for forming a growth film of the p type group III nitride semiconductor layer is 2 to 500 times.

9. The manufacturing method of a p type group III nitride semiconductor layer according to claim 1 wherein,
in repetitive film forming, a thickness of the p type group III nitride semiconductor layer formed in a single operation is 2 to 200 nm.

10. The manufacturing method of a p type group III nitride semiconductor layer according to claim 1 wherein,
the p type group III nitride semiconductor layer formed on the uppermost surface has a thickness smaller than any underlying p type group III nitride semiconductor layer.

11. The manufacturing method of a p type group III nitride semiconductor layer according to claim 10 wherein,
the p type group III nitride semiconductor layer formed on the uppermost surface has a thickness of not more than 100 nm.

12. The manufacturing method of a p type group III nitride semiconductor layer according to claim 10 wherein,
a repetitive number of forming a growth film of the p type group III nitride semiconductor layer on the uppermost surface is 1 to 50 times.

13. The manufacturing method of a p type group III nitride semiconductor layer according to claim 10 wherein,
natural cooling follows a film forming on the uppermost surface of the p type group III nitride semiconductor layer.

14. A light emitting device having a semiconductor layer containing a p type group III nitride semiconductor layer manufactured by the manufacturing method of a p type group III nitride semiconductor layer according to claim 1.
